(19) United States
(12) Patent Application Publication
(10) Pub. No.: US 2024/0369075 A1
(43) Pub. Date: Nov. 7, 2024

(54) FAN WITH SUPPORT FRAME HAVING SLIDING FASTENERS

(71) Applicant: Guangdong Titanium Tantalum Technology Co., Ltd, Huizhou (CN)

(72) Inventor: Zhenzhi Liang, Huizhou (CN)

(21) Appl. No.: 18/753,944

(22) Filed: Jun. 25, 2024

(30) Foreign Application Priority Data
May 4, 2023 (CN) 202321044207.X

(51) Int. Cl. F04D 29/64; F04D 19/00; H05K 7/20

(52) U.S. Cl. CPC F04D 29/646; H05K 7/20263; F04D 19/002

(57) ABSTRACT

A fan with a support frame having sliding fasteners includes at least one fan, a support frame, and a water-cooled row. Sliding fastener assemblies of support frame are arranged on the support frame, and snaps of sliding fastener of fan fitted with the sliding fastener assemblies of support frame are arranged on the fan, the sliding fastener assemblies of support frame including sliding fastener springs, sliding blocks, a pressing rod, fixing blocks for pressing rod and spring, and fixing blocks for support frame and spring. According to the above technical solution, it is very convenient to open and close the fan; and the fan can be well fixed on the support frame by the fit between a sliding fastener structure and a snap structure when closed, and can be opened and dismounted by pressing the pressing rod, featuring quick and easy dismounting and mounting, and simple structure.

### CROSS-REFERENCE TO RELATED APPLICATIONS

This application claims priority of Chinese Patent Application No. 202321044207. X, filed on May 4, 2023, the entire contents of which are incorporated herein by reference.

### TECHNICAL FIELD

The present disclosure relates to the field of radiators, and specifically to a fan with a support frame having sliding fasteners.

### BACKGROUND

A lot of heat can be generated during the operation of computer equipment, mechanical equipment, and heating equipment. Radiator, as a device for heat conducting and releasing, is commonly used. As computer systems are increasingly powerful in terms of computing power while generating more and more heat, a water-cooled cooling system, which is more effective in dissipating heat, is proposed.

In the prior art, some water-cooled cooling systems are mounted with fans, and fans on existing water-cooled radiators are usually fixed by means of nuts or in an affixing manner, with wires additionally connected to the electricity. When users need to perform the operations such as cleaning the radiator or replacing the fan, it is very inconvenient to dismount and mount the fan due to the need to unravel and organize the wires, and the additional need of a screwdriver and other tools to assist in completing the dismount and mount, affecting the users' experience seriously.

### SUMMARY

An objective of the present disclosure is to provide a fan with a support frame having sliding fasteners to overcome the deficiencies in the prior art.

The objective of the present disclosure is realized by the following technical solutions.

A fan with a support frame having sliding fasteners includes at least one fan, a support frame, and a water-cooled row. A radiator is a water-cooled radiator. The water-cooled row stores water-cooled liquid, and the fan cools the water-cooled liquid faster. The support frame is fixedly connected to an upper portion of the water-cooled row, and the support frame and the water-cooled row have the same size of rectangular plane to realize a better fit and improve the utilization of space. The fan is movably connected to an upper portion of the support frame, and it is convenient for the inclined opening and closing between the fan and the support frame. The fan and the support frame are electrically connected when affixed. Sliding fastener assemblies of support frame are arranged on the support frame, and the sliding fastener assemblies of support frame are movably connected to the fan by fitting with snaps of sliding fastener of fan. The snaps of sliding fastener of fan fitted with the sliding fastener assemblies of support frame are arranged on the fan, so that the snaps of sliding fastener of fan are movably connected to the support frame by fitting with the sliding fastener assemblies of support frame. The sliding fastener assemblies of support frame include sliding fastener spring, sliding blocks, a pressing rod, fixing blocks for support frame and spring, and fixing blocks for pressing rod and spring. When the fan is closed, the sliding blocks are moved, so that the snaps of sliding fastener of fan extend into the support frame, and then the sliding fastener springs provide a resetting force for the sliding blocks to allow the sliding blocks to be snap-fitted with the snaps of sliding fastener of fan. When the fan needs to be released, it is only necessary to press the pressing rod to push the sliding blocks to move, so that the snaps of sliding fastener of fan are released, and the fan is opened. The snaps of sliding fastener of fan correspond to the sliding blocks in position, so that the snaps of sliding fastener of fan can be snap-fitted and fixed by the sliding blocks during the opening and closing of the fan.

In one example, inclined surfaces of sliding block inclined downwards are arranged on top surfaces of the sliding blocks in contact with the snaps of sliding fastener of fan; and the inclined surfaces of sliding block, when come into contact with the snaps of sliding fastener of fan, change a downward pressure into a lateral thrust to move the sliding blocks, making room for the snaps of sliding fastener of fan to continue moving downwards.

In one example, the snap of sliding fastener of fan is integrally formed with a bottom surface of the fan in an L-shape; after the snaps of sliding fastener of fan enter the support frame, the sliding blocks are pushed back to the original position by the sliding fastener springs, and at this time, the sliding blocks are located on an upper portion of an L-shaped bottom edge to be snap-fitted with the snaps of sliding fastener of fan, so that the fan can be fixed; inclined surfaces of snaps of sliding fastener of fan inclined upwards are arranged on bottom surfaces of the snaps of sliding fastener of fan in contact with the sliding blocks, and when the snaps of sliding fastener of fan come into contact with the inclined surfaces of sliding block, the inclined surfaces change a downward pressure into a lateral thrust to move the sliding blocks, making room for the snaps of sliding fastener of fan to continue moving downwards.

In one example, the support frame is formed by a combination of an upper support frame and a lower support frame, the upper support frame is matched with the lower support frame in shape and is internally disposed with corresponding limit holes, and the sliding fastener assemblies of support frame are located between the upper support frame and the lower support frame; the sliding blocks, the pressing rod, and the fixing blocks for support frame and spring are laterally movable; the fixing block for support frame and spring is integrally formed with the lower support frame, and the fixing block for pressing rod and spring is integrally formed with the pressing rod; the fixing blocks for support frame and spring are connected to the fixing blocks for pressing rod and spring via the sliding fastener springs; the movable pressing rod and sliding blocks are movably connected to the support frame via the sliding fastener springs; one end of the pressing rod extends outside a side surface of the support frame in a penetrating manner; when the fan needs to be released, the extended pressing rod is pressed to push the sliding blocks, and the sliding blocks are moved to make room for the upward movement of the snaps of sliding fastener of fan, realizing the release of the fan; and the sliding block is integrally formed with the pressing rod, and moves with the movement of the pressing rod.

In one example, sliding fastener holes of upper support frame matched with the sliding fastener assemblies of support frame in position are arranged on the upper support frame to make room for the contact between the snaps of sliding fastener of fan and the sliding blocks; the sliding fastener holes of upper support frame are rectangular; and a side length of the sliding fastener hole of upper support frame is greater than that of a cross-section of the snap of sliding fastener of fan, and the sliding fastener holes of upper support frame correspond to the snaps of sliding fastener of fan in position, so that the snaps of sliding fastener of fan can penetrate through the sliding fastener holes of upper support frame.

In one example, the support frame is of a hollow rectangular structure for making room for air circulation between the water-cooled row and the fan; at least four screw holes of support frame are disposed at four corners of the support frame; when more than four screw holes of support frame are disposed, they are located on a longer side, which shortens the distance between the fixed screws and achieves a better fixation; screw holes of water-cooled row corresponding to the screw holes of support frame are disposed on the water-cooled row, and two screw holes corresponding in position can be connected via same screw; screws of support frame are arranged on the support frame for connecting the support frame to the water-cooled row; and the fixed connection between the support frame and the water-cooled row is realized by connecting the screw holes of support frame and the screw holes of water-cooled row via the same screw.

In one example, an electro-conductive interface is arranged at the support frame for powering the fan; at least one electro-conductive contact of support frame is arranged on the support frame, and is connected to the fan; electro-conductive contacts of fan matched with the electro-conductive contact of support frame are arranged on the fan 1; and the electro-conductive contacts of fan are fitted with the electro-conductive contact of support frame to realize electrical signal conduction.

In one example, integrally formed L-shaped support frame snaps are arranged on the support frame, the support frame snaps are L-shaped projections integrally formed with the support frame, and at least two support frame snaps are arranged; fan snap holes matched with the support frame snaps are disposed on the fan, and the fan snap holes correspond to the support frame snaps in shape, so that the fan snap holes can be obliquely inserted into the support frame snaps to achieve the movable snap-fitting between the fan and the support frame; and the fan and the support frame can be opened and closed in one way.

The present disclosure has the following advantageous effects.

In the present disclosure, due to the adoption of the above technical solutions, the fan can be fixed after being closed, and can be opened and dismounted by pressing the pressing rod, so it is very convenient to open and close the fan. When the radiator needs to be cleaned, the fan needs to be replaced and other operations need to be carried out, it is necessary to remove the fan directly only by opening the fan at a certain angle. The fan after being closed can be well fixed on the support frame by the fit between a sliding fastener structure and a snap structure, and the electro-conductive contact of fan and the electro-conductive contact of support frame are affixed to realize electrical signal connection. The fan requires neither additional wires for power supply and control, nor additional connection to a power supply port, featuring quick and easy dismounting and mounting, and simple structure.

### BRIEF DESCRIPTION OF THE DRAWINGS

To describe the technical solutions in the examples of the present disclosure more clearly, the accompanying drawings required for the examples are briefly described below. It is to be understood that the accompanying drawings in the following description merely show some examples of the present disclosure, and are not to be deemed as limiting the scope. Those of ordinary skill in the art can also derive other accompanying drawings from these accompanying drawings without creative efforts.

FIG. 1 is an exploded view I of the present disclosure.

FIG. 2 is an exploded view II of the present disclosure.

FIG. 3 is a perspective view I of the present disclosure.

FIG. 4 is a perspective view II of the present disclosure.

FIG. 5 is an enlargement view of portion A in FIG. 4.

FIG. 6 is a perspective view III of the present disclosure.

FIG. 7 is an enlargement view of portion B in FIG. 6.

FIG. 8 is an enlargement view of portion C in FIG. 6.

FIG. 9 is a perspective view IV of the present disclosure.

FIG. 10 is an enlargement view of portion D in FIG. 9.

Reference numerals and denotations thereof: 1—fan, 2—support frame, 3—water-cooled row, 4—electro-conductive interface, 5—sliding fastener spring, 6—sliding block, 7—inclined surface of sliding block, 8—pressing rod, 9—fixing block for pressing rod and spring, 10—fixing block for support frame and spring, 11—snap of sliding fastener of fan, 12—inclined surface of snaps of sliding fastener of fan, 13—electro-conductive contact of fan, 14—snap hole of fan, 21—lower support frame, 22—upper support frame, 23—sliding fastener hole of upper support frame, 24—screw hole of support frame, 25—screw of support frame, 26—electro-conductive contact of support frame, 27—snap of support frame, and 31—screw hole of water-cooled row.

### DETAILED DESCRIPTION

For the ease of understanding the present disclosure, the present disclosure will be described more comprehensively by reference to the related drawings below. Preferred embodiments of the present disclosure are provided in the accompanying drawings. However, the present disclosure can be realized in various forms and is not limited to the embodiments described herein, and these embodiments are provided for the purpose of making the disclosure of the present disclosure more thorough and comprehensive.

It is to be noted that when an element is “fixed” to another element, it can be directly to another element, or to a middle element. When an element is “connected to” another element, it can be connected to another element directly, or to a middle element. The terms “vertical,” “horizontal,” “left,” “right,” and similar expressions used herein are for illustrative purposes merely and are not intended to be a sole embodiment.

Unless otherwise specified, all technical and scientific terms used herein have the same meaning as those generally understood by those ordinary skilled in the art to which the present disclosure belongs. The terms used herein in the specification of the present disclosure are merely illustrative of the specific embodiments, and are not to be deemed as limiting the present disclosure. The term “and/or” includes any and all combinations of one or more related listed items.

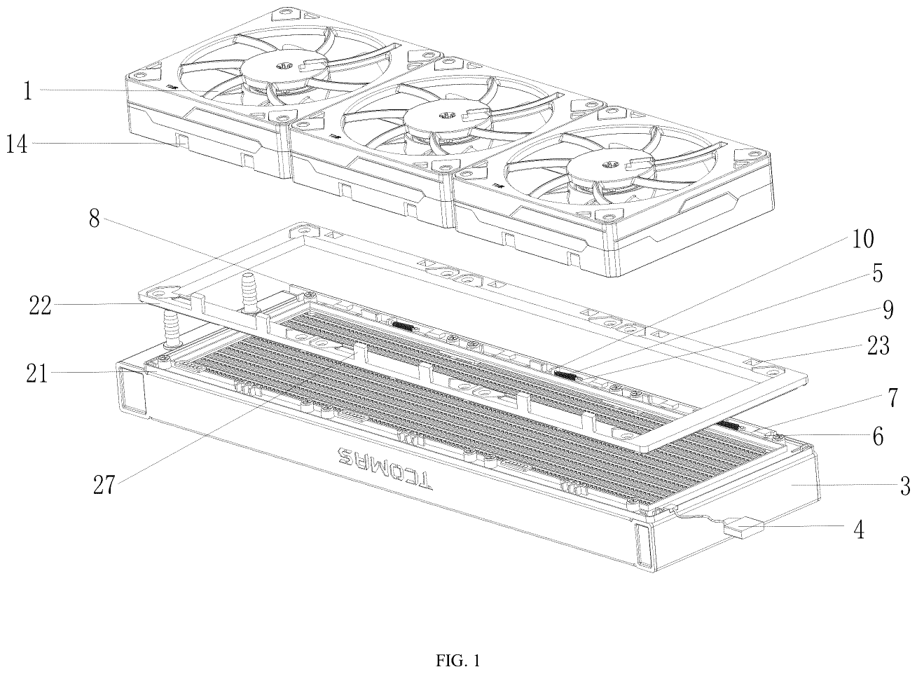

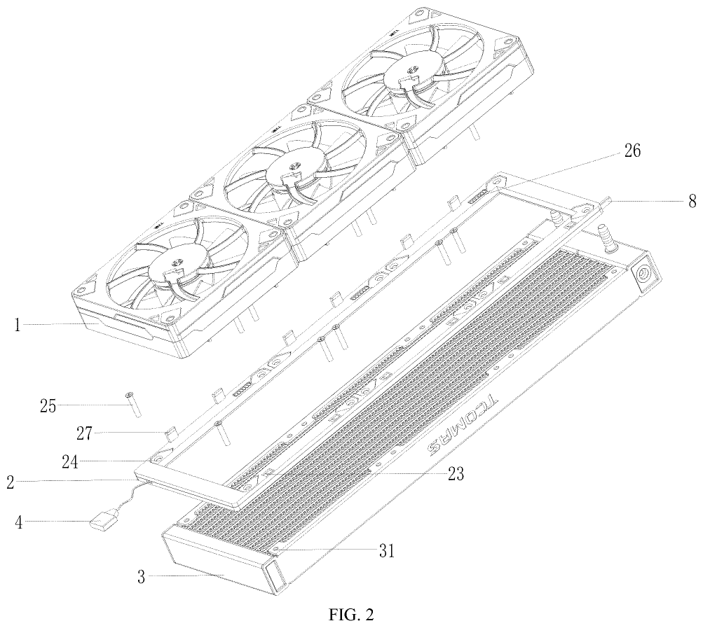

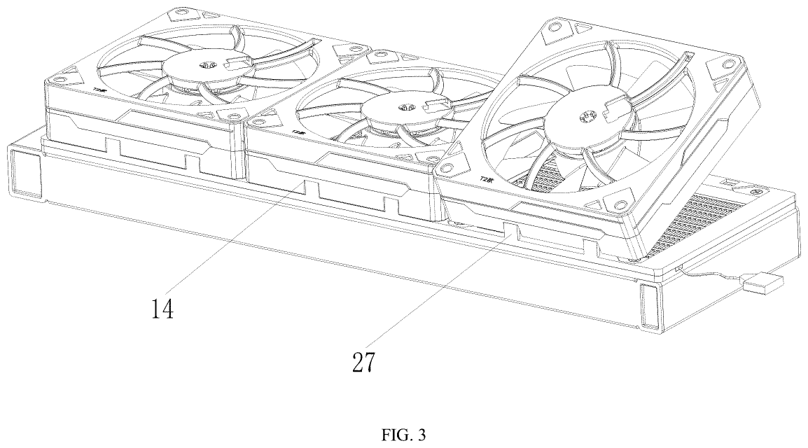

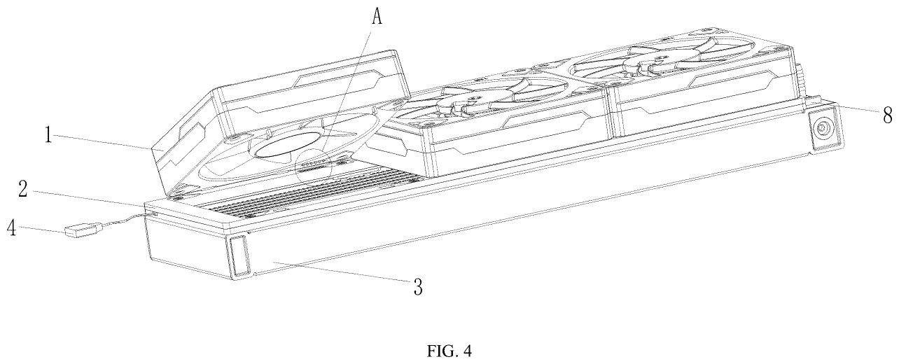

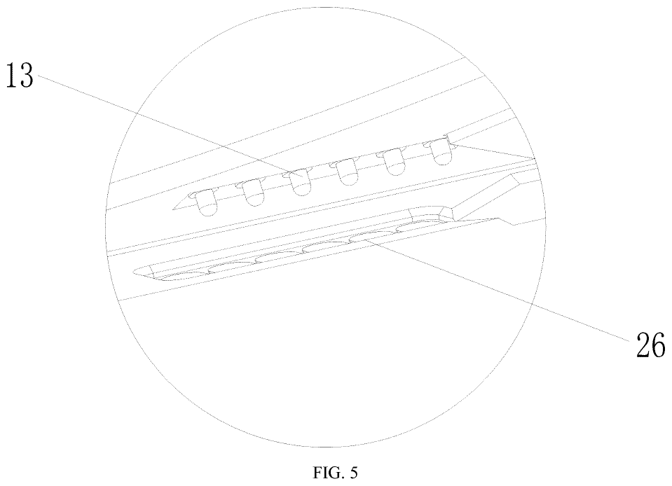

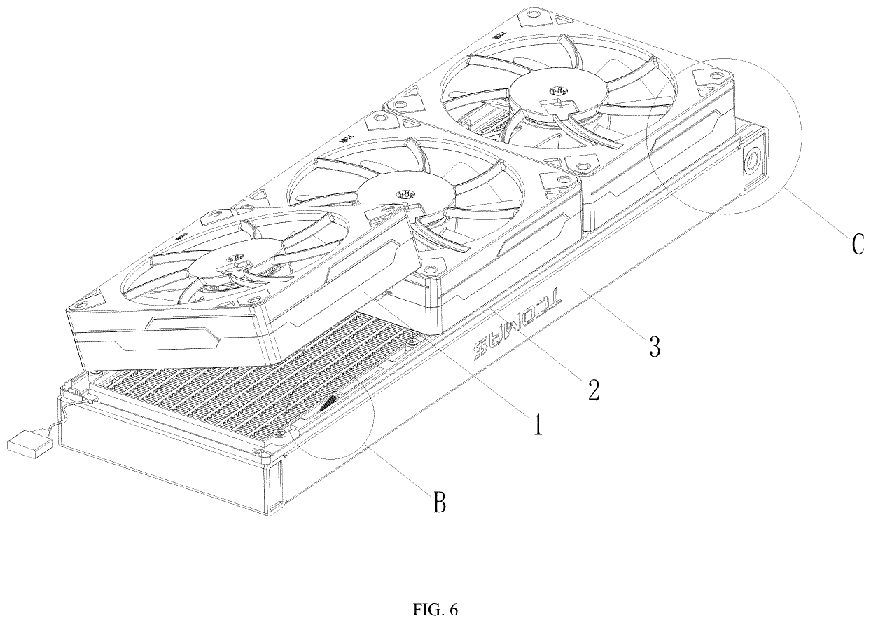

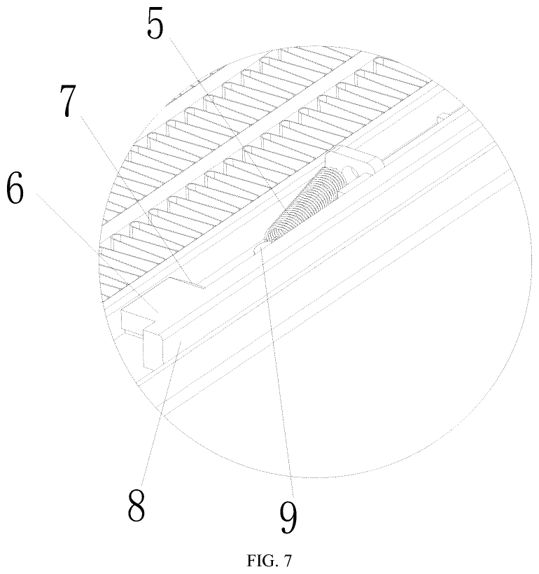

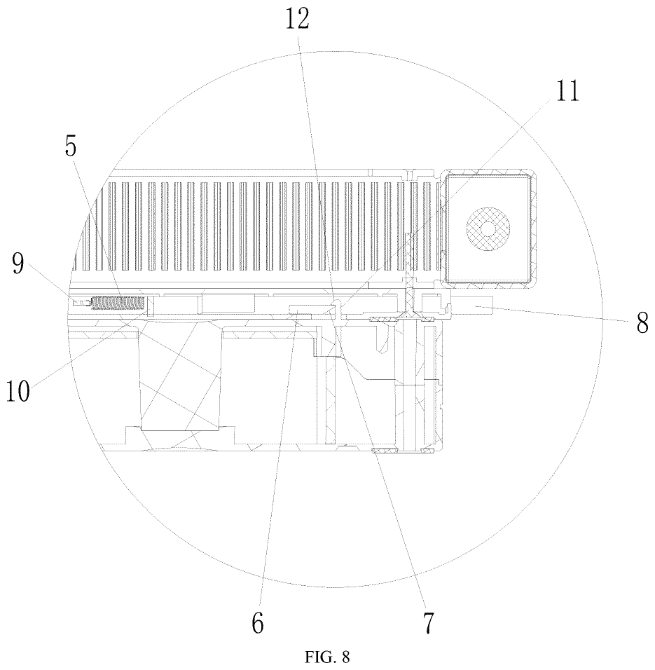

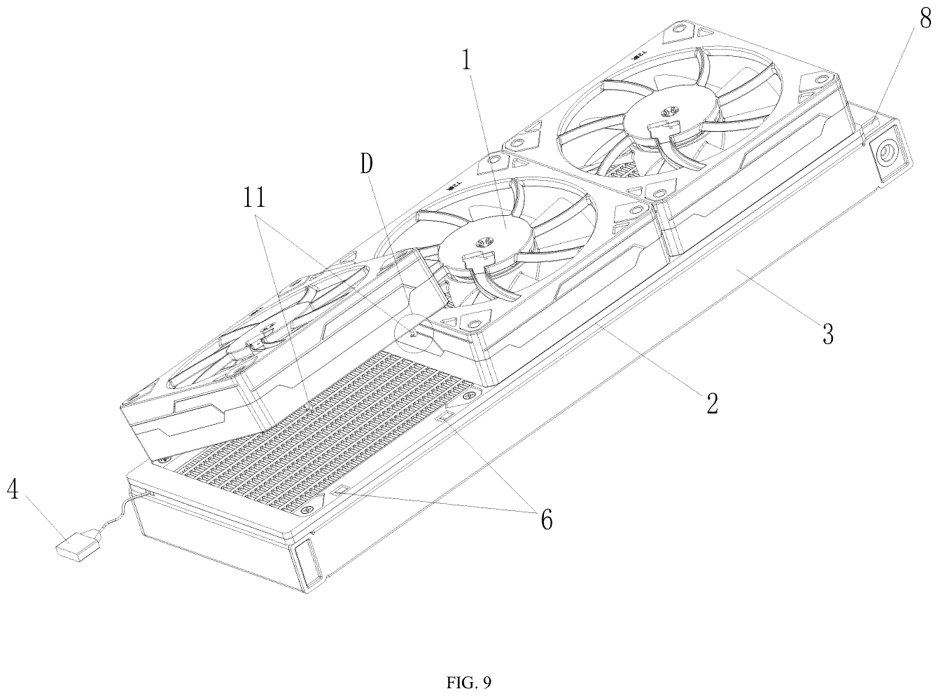

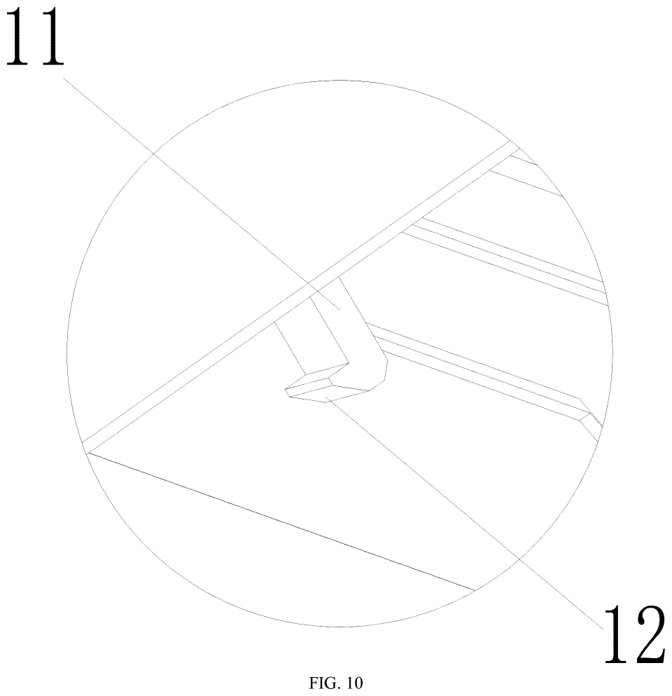

Examples of the present disclosure are shown in FIGS. 1 to 10.

A fan with a support frame having sliding fasteners includes at least one fan 1, a support frame 2, and a water-cooled row 3. The support frame 2 is fixedly connected to an upper portion of the water-cooled row 3, the fan 1 is movably connected to an upper portion of the support frame 2, and the fan 1 and the support frame 2 are electrically connected when affixed. Sliding fastener assemblies of support frame are arranged on the support frame 2, and snaps of sliding fastener of fan 11 fitted with the sliding fastener assemblies of support frame are arranged on the fan 1, the sliding fastener assemblies of support frame including sliding fastener springs 5, sliding blocks 6, a pressing rod 8, fixing blocks for support frame and spring 10, and fixing blocks for pressing rod and spring 9, and the snaps of sliding fastener of fan 11 corresponding to the sliding blocks 6 in position.

According to the above technical solution, a water-cooled radiator includes the fan 1, the support frame 2, and the water-cooled row 3; the water-cooled row 3 stores water-cooled liquid, and the fan 1 cools the water-cooled liquid faster; the support frame 2 is fixedly connected to the upper portion of the water-cooled row 3, and the support frame 2 and the water-cooled row 3 have the same size of rectangular plane to realize a better fit and improve the utilization of space; the fan 1 is movably connected to the upper portion of the support frame 2, and it is convenient for the inclined opening and closing between the fan 1 and the support frame 2; the fan 1 and the support frame 2 are electrically connected when affixed, so that the fan can be controlled to run; the sliding fastener assemblies of support frame of the support frame 2 are movably connected to the fan 1 by fitting with the snaps of sliding fastener of fan 11; the snaps of sliding fastener of fan 11 fitted with the sliding fastener assemblies of support frame are arranged on the fan 1, so that the snaps of sliding fastener of fan 11 are movably connected to the support frame 2 by fitting with the sliding fastener assemblies of support frame; the sliding fastener assemblies of support frame include the sliding fastener spring 5, the sliding blocks 6, the pressing rod 8, the fixing blocks for support frame and spring 10, and the fixing blocks for pressing rod and spring 9; when the fan 1 is closed, the sliding blocks 6 are moved, so that the snaps of sliding fastener of fan 11 extend into the support frame 2, and then the sliding fastener springs 5 provide a resetting force for the sliding blocks 6 to allow the sliding blocks 6 to be snap-fitted with the snaps of sliding fastener of fan 11; when the fan 1 needs to be released, it is only necessary to press the pressing rod 8 to push the sliding blocks 6 to move, so that the snaps of sliding fastener of fan 11 are released, and the fan 1 is opened; and the snaps of sliding fastener of fan 11 correspond to the sliding blocks 6 in position, so that the snaps of sliding fastener of fan 11 can be snap-fitted and fixed by the sliding blocks 6 during the opening and closing of the fan 1.

Preferably, inclined surfaces of sliding block 7 inclined downwards are arranged on top surfaces of the sliding blocks 6 in contact with the snaps of sliding fastener of fan 11.

According to the above technical solution, the inclined surfaces of sliding block 7, when come into contact with the snaps of sliding fastener of fan 11, change a downward pressure into a lateral thrust to move the sliding blocks 6, making room for the snaps of sliding fastener of fan 11 to continue moving downwards.

Preferably, the snap of sliding fastener of fan 11 is integrally formed with a bottom surface of the fan 1 in an L-shape, and inclined surfaces of snaps of sliding fastener of fan 12 inclined upwards are arranged on bottom surfaces of the snaps of sliding fastener of fan 11 in contact with the sliding blocks 6.

According to the above technical solution, the design of L-shape causes the snaps of sliding fastener of fan 11 to enter the support frame 2, and the sliding blocks 6 are pushed back to the original position by the sliding fastener springs 5, and at this time, the sliding blocks 6 are located on an upper portion of an L-shaped bottom edge to be snap-fitted with the snaps of sliding fastener of fan 11, so that the fan 1 can be fixed; and the inclined surface of snaps of sliding fastener of fan 12, when the snaps of sliding fastener of fan 11 come into contact with the inclined surfaces of sliding block 7, change a downward pressure into a lateral thrust to move the sliding blocks 6, making room for the snaps of sliding fastener of fan 11 to continue moving downwards.

Preferably, the support frame 2 is formed by a combination of an upper support frame 22 and a lower support frame 21, the sliding fastener assemblies of support frame are located between the upper support frame 22 and the lower support frame 21, the fixing block for support frame and spring 10 is integrally formed with the lower support frame 21, the fixing block for pressing rod and spring 9 is integrally formed with the pressing rod 8, the fixing blocks for support frame and spring 10 are connected to the fixing blocks for pressing rod and spring 9 via the sliding fastener springs 5, one end of the pressing rod 8 extends outside a side surface of the support frame 2 in a penetrating manner, and the sliding block 6 is integrally formed with the pressing rod 8.

According to the above technical solution, the support frame 2 is matched with the lower support frame 21 in shape, and is internally disposed with corresponding limit holes; the sliding fastener assemblies of support frame are located between the upper support frame 22 and the lower support frame 21; the sliding blocks 6, the pressing rod 8, and the fixing blocks for support frame and spring 10 are laterally movable; the fixing block for support frame and spring 10 is integrally formed with the lower support frame 21, and the fixing block for pressing rod and spring 9 is integrally formed with the pressing rod 8; the fixing blocks for support frame and spring 10 are connected to the fixing blocks for pressing rod and spring 9 via the sliding fastener springs 5; the movable pressing rod 8 and sliding blocks 6 are movably connected to the support frame 2 via the sliding fastener springs 5; one end of the pressing rod 8 extends outside the side surface of the support frame 2 in a penetrating manner; when the fan 1 needs to be released, the extended pressing rod 8 is pressed to push the sliding blocks 6, and the sliding blocks 6 are moved to make room for the upward movement of the snaps of sliding fastener of fan 11, realizing the release of the fan 1; and the sliding block 6 is integrally formed with the pressing rod 8, and moves with the movement of the pressing rod 8.

Preferably, sliding fastener holes of upper support frame 23 matched with the sliding blocks 6 of the sliding fastener assemblies of support frame in position are disposed on the upper support frame 22, the sliding fastener holes of upper support frame 23 being rectangular, a side length of the sliding fastener hole of upper support frame 23 being greater than that of a cross-section of the snap of sliding fastener of fan 11, and the sliding fastener hole of upper support frame 23 corresponding to the snap of sliding fastener of fan 11 in position.

According to the above technical solution, the sliding fastener holes of upper support frame 23, matched with the sliding blocks 6 of the sliding fastener assemblies of support frame in position, are disposed on the upper support frame 22 to make room for the contact between the snaps of sliding fastener of fan 11 and the sliding blocks 6; the sliding fastener holes of upper support frame 23 are rectangular holes, and a side length of the rectangular hole is greater than that of a cross-section of the snap of sliding fastener of fan 11; and the sliding fastener holes of upper support frame 23 correspond to the snaps of sliding fastener of fan 11 in position, so that the snaps of sliding fastener of fan 11 can penetrate through the sliding fastener holes of upper support frame 23.

Preferably, the support frame 2 is of a hollow rectangular structure, at least four screw holes of support frame 24 are disposed on the support frame 2, and screw holes of water-cooled row 31 corresponding to the screw holes of support frame 24 are disposed on the water-cooled row 3; and screws of support frame 25 are arranged on the support frame 2, and the screws of support frame 25 penetrate through the screw holes of support frame 24 and are fixed on the screw holes of water-cooled row 31.

According to the above technical solution, the hollow rectangle makes room for air circulation between the water-cooled row 3 and the fan 1; the four screw holes of support frame 24 disposed on the support frame 24 are located at four corners of the support frame 2; when more than four screw holes of support frame 24 are disposed, the screw holes are located on a longer side, which shortens the distance between the fixed screws and achieves a better fixation; the screw holes of water-cooled row 31 corresponding to the screw holes of support frame 24 in position are connected via the same screw; the screws of support frame 25 are used for connecting the support frame 2 to the water-cooled row 3; and the screws of support frame 25 penetrate through the screw holes of support frame 24 and are fixed on the screw holes of water-cooled row 31, and the fixed connection between the support frame 2 and the water-cooled row 3 is realized by connecting the screw holes of support frame 24 and the screw holes of water-cooled row 31 via the same screw.

Preferably, an electro-conductive interface 4 is arranged at the support frame 2, at least one electro-conductive contact of support frame 26 is arranged on the support frame 2, and electro-conductive contacts of fan 13 matched with the electro-conductive contact of support frame 26 are arranged on the fan 1.

According to the above technical solution, the electro-conductive interface 4 of the support frame 2 powers the fan 1; the electro-conductive contact of support frame 26 of the support frame 2 is connected to the fan 1, and the electro-conductive contacts of fan 13 matched with the electro-conductive contact of support frame 26 realize electrical signal conduction.

Preferably, the electro-conductive interface 4 is arranged at the support frame 2, integrally formed L-shaped support frame snaps 27 are arranged on the support frame 2, and fan snap holes 14 matched with the support frame snaps 27 are disposed on the fan 1.

According to the above technical solution, the integrally formed L-shaped support frame snaps 27 arranged on the support frame 2 are L-shaped projections, and at least two support frame snaps 27 are arranged; the fan snap holes 14 matched with the support frame snaps 27 are disposed on the fan 1, and the fan snap holes 14 correspond to the support frame snaps 27 in shape, so that the fan snap holes 14 can be obliquely inserted into the support frame snaps 27 to achieve the movable snap-fitting between the fan 1 and the support frame 2; and the fan 1 and the support frame 2 can be opened and closed in one way.

An operation principle is as follows. By means of the limit fit between shapes of the sliding fastener assembly of support frame and the snaps of sliding fastener of fan 11, the fan 1 is fixed on the support frame 2, and the fan 1 can be released by pressing the pressing rod 8, which is easy to dismount and mount. The movable snap-fitting between the support frame snaps 27 and the fan snap holes 14 realizes the opening and closing of the fan 1 in one way. Finally, the fan 1 is controlled to run by electrically connecting the electro-conductive contacts of fan 13 to the electro-conductive contact of support frame 26.

When mounted, the fan 1 is closed and placed flatly after the fan snap holes 14 disposed on the fan 1 of the present disclosure are inserted into the corresponding support frame snaps 27, and the radiator of the present disclosure is placed and fixed to a heating point that needs to be cooled. Finally, the electro-conductive interface 4 is connected to a power supply hole corresponding to a motherboard to complete the mounting. When dismounted, the fan 1 is released by pushing the pressing rod 8, and the fan 1 after being opened to a certain angle is removed by tilting upwards to complete the dismounting.

The above-described examples are merely several embodiments of the present disclosure, which are described in a more specific and detailed manner, but are not to be construed as a limitation on the scope of the present disclosure. It is to be noted that for those ordinary skilled in the art, several deformations and improvements can be made without departing from the conception of the present disclosure, all of which fall within the scope of protection of the present disclosure. Therefore, the scope of protection of the present disclosure is to be defined by the attached claims.

1. A fan with a support frame having sliding fasteners, comprising at least one fan (1), a support frame (2), and a water-cooled row (3), wherein the support frame (2) is fixedly connected to an upper portion of the water-cooled row (3), the fan (1) is movably connected to an upper portion of the support frame (2), and the fan (1) and the support frame (2) are electrically connected when affixed; and sliding fastener assemblies of support frame are arranged on the support frame (2), and snaps of sliding fastener of fan (11) fitted with the sliding fastener assemblies of support frame are arranged on the fan (1), the sliding fastener assemblies of support frame comprising sliding fastener springs (5), sliding blocks (6), a pressing rod (8), fixing blocks for pressing rod and spring (9), and fixing blocks for support frame and spring (10), and the snaps of sliding fastener of fan (11) corresponding to the sliding blocks (6) in position.

2. The fan with a support frame having sliding fasteners according to claim 1, wherein inclined surfaces of sliding block (7) inclined downwards are arranged on top surfaces of the sliding blocks (6) in contact with the snaps of sliding fastener of fan (11).

3. The fan with a support frame having sliding fasteners according to claim 1, wherein the snap of sliding fastener of fan (11) is integrally formed with a bottom surface of the fan (1) in an L-shape, and inclined surfaces of snaps of sliding fastener of fan (12) inclined upwards are arranged on bottom surfaces of the snaps of sliding fastener of fan (11) in contact with the sliding blocks (6).

4. The fan with a support frame having sliding fasteners according to claim 1, wherein the support frame (2) is formed by a combination of an upper support frame (22) and a lower support frame (21), the sliding fastener assemblies of support frame are located between the upper support frame (22) and the lower support frame (21), the fixing block for support frame and spring (10) is integrally formed with the lower support frame (21), the fixing block for pressing rod and spring (9) is integrally formed with the pressing rod (8), the fixing blocks for support frame and spring (10) are connected to the fixing blocks for pressing rod and spring (9) via the sliding fastener springs (5), one end of the pressing rod (8) extends outside a side surface of the support frame (2) in a penetrating manner, and the sliding block (6) is integrally formed with the pressing rod (8).

5. The fan with a support frame having sliding fasteners according to claim 4, wherein sliding fastener holes of upper support frame (23) matched with the sliding blocks (6) of the sliding fastener assemblies of support frame in position are disposed on the upper support frame (22), the sliding fastener holes of upper support frame (23) being rectangular, a side length of the sliding fastener hole of upper support frame (23) being greater than that of a cross-section of the snap of sliding fastener of fan (11), and the sliding fastener hole of upper support frame (23) corresponding to the snap of sliding fastener of fan (11) in position.

6. The fan with a support frame having sliding fasteners according to claim 1, wherein the support frame (2) is of a hollow rectangular structure, at least four screw holes of support frame (24) are disposed on the support frame (2), and screw holes of water-cooled row (31) corresponding to the screw holes of support frame (24) are disposed on the water-cooled row (3); and screws of support frame (25) are arranged on the support frame (2), and the screws of support frame (25) penetrate through the screw holes of support frame (24) and are fixed on the screw holes of water-cooled row (31).

7. The fan with a support frame having sliding fasteners according to claim 1, wherein an electro-conductive interface (4) is arranged at the support frame (2), at least one electro-conductive contact of support frame (26) is arranged on the support frame (2), and electro-conductive contacts of fan (13) matched with the electro-conductive contact of support frame (26) are arranged on the fan (1).

8. The fan with a support frame having sliding fasteners according to claim 1, wherein integrally formed L-shaped support frame snaps (27) are arranged on the support frame (2), and fan snap holes (14) matched with the support frame snaps (27) are disposed on the fan (1).
